(19) United States
(12) Patent Application Publication
(10) Pub. No.: US 2026/0033197 A1
(43) Pub. Date: Jan. 29, 2026

(54) DISPLAY PANEL

(71) Applicant: HKC CORPORATION LIMITED, SHENZHEN (CN)

(72) Inventors: Dongmei WEI, SHENZHEN (CN); Jie CHEN, SHENZHEN (CN); Fengzhen DANG, SHENZHEN (CN); Lidan YE, SHENZHEN (CN)

(73) Assignee: HKC CORPORATION LIMITED, SHENZHEN (CN)

(21) Appl. No.: 19/264,240

(22) Filed: Jul. 9, 2025

(30) Foreign Application Priority Data
Jul. 23, 2024 (CN) 202410996877.4

(51) Int. Cl. H10K 59/131; H10K 59/127

(52) U.S. Cl. CPC H10K 59/1315; H10K 59/1275

(57) ABSTRACT

A display panel is disclosed. The display panel includes a glass substrate, multiple light-emitting units, multiple first bonding portions, multiple second bonding portions, a silicon-based driving substrate, and a conductive adhesive layer. The glass substrate includes multiple first conductive vias and multiple second conductive vias extending from the first surface to the second surface. The first bonding portions are electrically connected to the corresponding anode electrodes through the corresponding first conductive vias. The second bonding portions are electrically connected to the cathode electrodes through the corresponding second conductive vias. The silicon-based driving substrate includes multiple first bonding electrodes and second bonding electrodes. The conductive adhesive layer is arranged between the second bonding portion and the second bonding electrode to electrically connect and bond the second bonding portion and the second bonding electrode together.

### CROSS-REFERENCE TO RELATED APPLICATIONS

This application claims priority to Chinese Patent Application No. 202410996877.4, filed on Jul. 23, 2024, the content of which is herein incorporated by reference in its entirety.

### TECHNICAL FIELD

The present disclosure relates to the technical field of displays, and in particular to a display panel.

### BACKGROUND

A monocrystalline silicon driving backplanes is a driving substrate formed using semiconductor devices as driving units, which are formed through Complementary Metal Oxide Semiconductor (CMOS) processes. Compared with the conventional Active-matrix organic light-emitting diode (AMOLED) panels that use amorphous silicon, microcrystalline silicon, or low-temperature polysilicon thin-film transistors as backplanes, monocrystalline silicon driving backplanes have a higher carrier mobility. Therefore, silicon-based organic light-emitting diode (OLED) display panels currently represent the display type with optimal performance applied in products in the AR/VR field.

Currently in silicon-based OLED display panels, traditionally externally bonded display chips are integrated into the silicon driving backplane. The preparing process involves evaporating and depositing OLED light-emitting devices on the silicon-based driving substrate. Specifically, first depositing anode electrodes, then fabricating a pixel defining layer, followed by sequentially depositing organic light-emitting layers and cathode electrodes. In this way, pixel units with smaller sizes can be prepared, which achieves a display fineness that exceeds the retinal level and have many advantages such as high resolution, high integration degree, low power consumption, small volume, and light weight.

However, directly evaporating and depositing OLED light-emitting devices on silicon-based driving substrates may have an impact on the silicon-based driving circuits, resulting in the damage and incapability of the driving circuit, which thus increases the cost.

### SUMMARY

A technical solution adopted in the present disclosure is to provide a display panel, including:
a glass substrate, including a first surface and a second surface opposite to each other and having a plurality of conductive vias extending from the first surface to the second surface; the plurality of conductive vias including a plurality of first conductive vias and a plurality of second conductive vias;
a plurality of light-emitting units, disposed on the first surface of the glass substrate; each of the light-emitting units including an anode electrode, an organic light-emitting layer, and a cathode electrode sequentially stacked in a direction away from the glass substrate;
a plurality of first bonding portions, each of the first bonding portions being electrically connected to a corresponding anode electrode through a corresponding first conductive via of the first conductive vias;
a plurality of second bonding portions each of the second bonding portions being electrically connected to a corresponding cathode electrode through a corresponding second conductive via of the second conductive vias;
a silicon-based driving substrate, disposed on the second surface of the glass substrate, including a plurality of first bonding electrodes and a plurality of second bonding electrodes; the plurality of first bonding electrodes being aligned and bonded to the plurality of first bonding portions in one-to-one correspondence;
a conductive adhesive layer, configured to conduct and adhere the second bonding portions to the second bonding electrodes together.

Another technical solution adopted in the present disclosure is to provide a display panel, including:
a glass substrate, including a plurality of first bonding portions and a plurality of second bonding portions, wherein each of the first bonding portions is electrically connected to a corresponding anode electrode, and each of the second bonding portions is electrically connected to a corresponding cathode electrode;
a silicon-based driving substrate, aligned and bonded to the glass substrate, wherein the silicon-based driving substrate includes a plurality of first bonding electrodes and at least one second bonding electrode; the plurality of first bonding electrodes are aligned and bonded to the plurality of first bonding portions in one-to-one correspondence; and
a conductive adhesive layer, configured to conduct and adhere the at least one second bonding portion to the at least one second bonding electrode together.

Another technical solution adopted in the present disclosure is to provide a display panel, including:
a glass substrate, including a plurality of first bonding portions and at least one second bonding portion;
a plurality of light-emitting units, disposed on the glass substrate, wherein each of the light-emitting units includes an anode electrode, an organic light-emitting layer, and a cathode electrode sequentially stacked on the glass substrate, a corresponding anode electrode is electrically connected to a corresponding one of the first bonding portions, and a corresponding cathode electrode is electrically connected to a corresponding one of the at least one second bonding portion;
a silicon-based driving substrate, aligned and bonded to the glass substrate, wherein the silicon-based driving substrate includes a plurality of first bonding electrodes and at least one second bonding electrode; the plurality of first bonding electrodes are aligned and bonded to the plurality of first bonding portions in one-to-one correspondence; and
a conductive adhesive layer, configured to conduct and adhere the at least one second bonding portion to the at least one second bonding electrodes together.

### BRIEF DESCRIPTION OF THE DRAWINGS

FIG. 1 is a schematic structural view of a display panel according to first embodiments of the present disclosure.

FIG. 2 is a bottom view of the glass substrate in the display panel shown in FIG. 1.

FIG. 3 is a schematic structural view in which the conductive adhesive layer is disposed on the glass substrate shown in FIG. 2.

FIG. 4 is a schematic structural view of the silicon-based driving substrate in the display panel shown in FIG. 1.

FIG. 5 is a partially enlarged view of area A in the display panel shown in FIG. 1.

FIG. 6 is a schematic structural view of the structure shown in FIG. 5 without the conductive adhesive layer.

### DETAILED DESCRIPTIONS

Technical solutions of the embodiments of the present disclosure will be clearly and comprehensively described by referring to the accompanying drawings. Obviously, the embodiments described herein are only a part of, but not all of, the embodiments of the present disclosure. Based on the embodiments in the present disclosure, all other embodiments obtained by a person of ordinary skill in the art without any creative work shall fall within the scope of the present disclosure.

Terms “first”, “second”, and “third” in the embodiments of the present disclosure are only used for descriptive purposes, and cannot be understood as indicating or implying relative importance or implicitly indicating the number of indicated technical features. Therefore, features defined with “first”, “second”, and “third” may explicitly or implicitly include at least one of the features. In the description of the present disclosure, “a plurality of” means at least two, such as two, three, etc., unless specifically defined otherwise. In the embodiments of the present disclosure, all directional indications (such as up, down, left, right, front, back, etc.) are only used to explain the relative position relationship, motion, etc. between components in a specific attitude (as shown in the FIG.). If the specific attitude changes, the directional indication will change accordingly. In addition, terms “including”, “having”, and any variations thereof are intended to cover non-exclusive inclusions. For example, a process, method, system, product, or device that includes a series of operations or units is not limited to the listed operations or units, but optionally includes unlisted operations or units, or optionally also includes other operations or units inherent to these processes, methods, products or equipment.

The reference to “an embodiment” means that a specific feature, structure or characteristic described in connection with an embodiment may be included in at least one embodiment of the present disclosure. The appearance of “an embodiment” in various places in the specification does not necessarily refer to the same embodiment, nor is it an independent or alternative embodiment mutually exclusive with other embodiments. It is understood explicitly and implicitly by those skilled in the art that the embodiments described in the present disclosure can be combined with other embodiments.

The present disclosure will be described in detail below with reference to the accompanying drawings and embodiments.

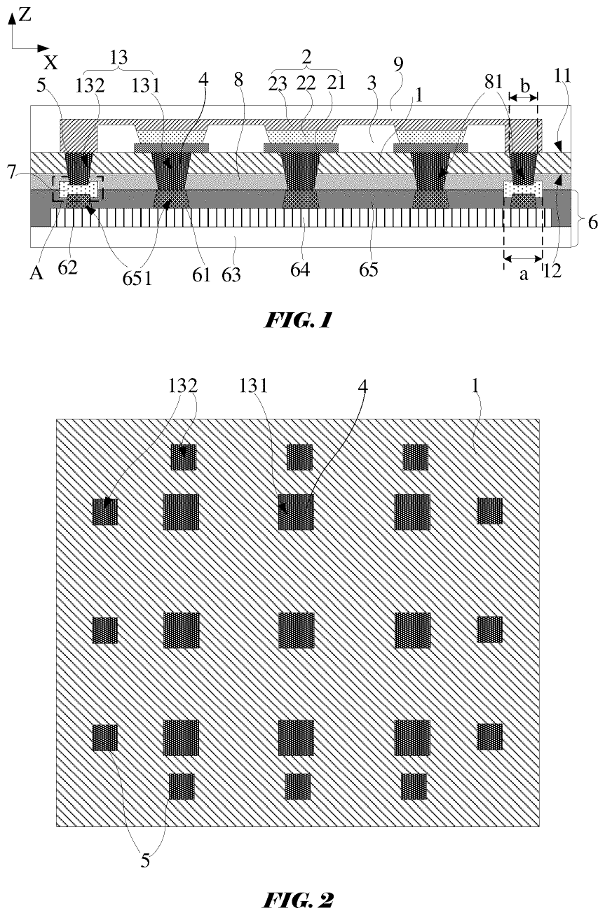

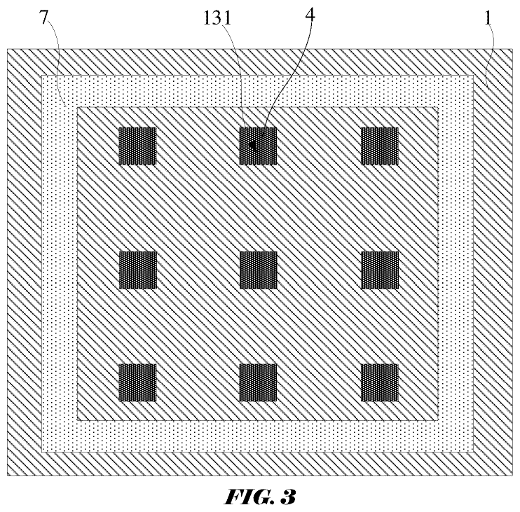

As shown in FIG. 1, FIG. 1 is a schematic structural view of a display panel according to first embodiments of the present disclosure, FIG. 2 is a bottom view of the glass substrate in the display panel shown in FIG. 1, FIG. 3 is a schematic structural view in which the conductive adhesive layer is disposed on the glass substrate shown in FIG. 2. The present disclosure provides a display panel, which may be an OLED display panel. The display panel may include a glass substrate 1, multiple light-emitting units 2, multiple first bonding portions 4, multiple second bonding portions 5, a silicon-based driving substrate 6, and a conductive adhesive layer 7.

The glass substrate 1 may include a first surface 11 and a second surface 12 opposite to each other. The glass substrate 1 may have multiple conductive vias 13 extending from the first surface 11 to the second surface 12. Specifically, laser-induced etching technology may be used to form vias in the glass substrate 1, then the vias may be filled with conductive materials to form the conductive vias 13, so that an electrical connection may be achieved between the first surface 11 and second surface 12 of the glass substrate 1 through the conductive vias 13. A diameter of the conductive via 13 may be between 50 micrometers and 100 micrometers. It should be understood that too small spacing between adjacent conductive vias 13 may affect the structural strength of the glass substrate 1, causing damage to the glass substrate 1, while too large spacing may reduce the density of conductive vias 13. Therefore, the spacing between adjacent conductive vias 13 may be between 50 micrometers and 150 micrometers. Specifically, the multiple conductive vias 13 may include multiple first conductive vias 131 and multiple second conductive vias 132.

The multiple light-emitting units 2 may be disposed on the first surface 11 of the glass substrate 1. Each of the light-emitting units 2 may include an anode electrode 21, an organic light-emitting layer 22, and a cathode electrode 23, which sequentially stacked in a direction away from the glass substrate 1. Specifically, a pixel defining layer 3 may be further disposed on the first surface 11 of the glass substrate 1. The pixel defining layer 3 may protrude from the glass substrate 1 and enclose to form multiple pixel accommodation regions (not shown), in which the multiple light-emitting units 2 may be respectively disposed. the multiple pixel accommodation regions may be arranged in one-to-one correspondence with the multiple first conductive vias 131.

An anode electrode 21 may be disposed on the surface of the glass substrate 1 exposed with respect to the pixel accommodation region. A pixel defining layer 3 may cover edges of the anode electrodes 21 to prevent the anode electrodes 21 of adjacent light-emitting units 2 from contacting with each other, which may lead to signal crosstalk. An organic light-emitting layer 22 may be disposed on a surface of an anode electrode 21 away from the glass substrate 1, and a cathode electrode 23 may be disposed on a surface of the organic light-emitting layer 22 away from the anode electrode 21, covering the organic light-emitting layers 22 of multiple light-emitting units 2 to form a common cathode at the whole surface. An anode electrode 21 may transmit anode driving signals and a cathode electrode 23 may transmit cathode driving signals to an organic light-emitting layer 22 to drive the organic light-emitting layer 22 for light emission.

In some embodiments, the light-emitting units 2 may include those ones with different emission colors, such as red light-emitting unit 2, green light-emitting unit 2, and blue light-emitting unit 2, to achieve color display. Specifically, the emission color may be determined by an organic light-emitting layer 22. In some embodiments, in another embodiments, the light-emitting units 2 may also be light-emitting units 2 of the same color, e.g., white, red, green, blue, or others, which may be set according to practical needs. For example, if the light-emitting units 2 emit white light, the brightness of the light-emitting units 2 may be controlled to achieve grayscale display. Additionally, a color filter layer may be added above the light-emitting units 2 to achieve color display. For example, if the light-emitting units 2 emit blue light, a red quantum dot layer may be added above some of the light-emitting units 2, and a green quantum dot layer may be added above some of the light-emitting units 2, so as to achieve color display.

Multiple first bonding portions 4 may be disposed on the second surface 12 of the glass substrate 1. Each first bonding portion 4 may be electrically connected to an anode electrode 21 through the corresponding first conductive via 131, such that an anode driving signal may be transmitted to the anode electrode 21 of a corresponding light-emitting unit 2 through the first conductive via 131. Multiple second bonding portions 5 may be disposed on the second surface 12 of the glass substrate 1. Each second bonding portion 5 may be electrically connected to a cathode electrode 23 through a corresponding second conductive via 132, such that the cathode driving signal may be transmitted to the cathode electrode 23 of a light-emitting unit 2 through the second conductive via 132. In some embodiments, the glass substrate 1 may include multiple first bonding portions 4 and at least one second bonding portion 5. Each of the first bonding portions 4 may be electrically connected to a corresponding anode electrode. Each of the at least one second bonding portion 5 may be electrically connected to a corresponding cathode electrode 23.

A silicon-based driving substrate 6 may be disposed at a side of the second surface 12, and the silicon-based driving substrate 6 may include multiple first bonding electrodes 61 and at least one second bonding electrode 62. In some embodiments, the silicon-based driving substrate 6 may be aligned and bonded to the glass substrate 1. The first bonding electrodes 61 may be aligned and bonded to the first bonding portions 4 in one-to-one correspondence, so as to control the light emitting units 2 corresponding to the first bonding parts 4 to emit light. As the light-emitting units 2, the first bonding portions 4, and the second bonding portions 5 may be arranged on the two opposite surfaces of the glass substrate 1 respectively, the first bonding portions 4 may be contacted with and electrically connected with the anode electrodes 21 of the corresponding light-emitting units 2 through the first conductive vias 131, and the second bonding portions 5 may be contacted with and electrically connected with the cathode electrodes 23 of the light-emitting units 2 through the second conductive vias 132. Thus, after the first bonding portions 4 and the second bonding portions 5 may be bonded to the first bonding electrodes 61 and the second bonding electrodes 62 of the silicon-based driving substrate 6 respectively, the electrical coupling between the light-emitting units 2 and the silicon-based driving substrate 6 may be achieved, enabling the silicon-based driving substrate 6 to drive the light-emitting units 2 to emit light. In this way, the light-emitting units 2 first may be fabricated on the glass substrate 1 and then bonded to the silicon-based driving substrate 6, rather than the light-emitting units 2 being directly fabricated on the silicon-based driving substrate 6, thereby avoiding the problem of damaging to pixel driving circuits and then resulting in a reduction in the product yield which is caused by directly fabricating the light-emitting units 2 on the silicon-based driving substrate 6.

A conductive adhesive layer 7 may be disposed between the second bonding portions 5 and the second bonding electrodes 62, so as to conduct and adhere the second bonding portions 5 to the second bonding electrodes 62 together. In some embodiments, a conductive adhesive layer 7 may be configured for conducting and adhering the at least one second bonding portion 5 to the at least one second bonding electrode 62 together. Specifically, the conductive adhesive layer 7 may include an adhesive (not shown) and conductive particles (not shown). The adhesive serves as the matrix of the conductive adhesive layer 7, which may be used to carry the conductive particles and provide adhering ability to adhere the second bonding portions 5 to the second bonding electrodes 62. Specifically, the adhesive may be made from resin material. The conductive particles may be used to form a conductive path in the matrix to make the second bonding portions 5 and the second bonding electrodes 62 conduct, enabling the silicon-based driving substrate 6 to transmit a cathode driving signal to the second bonding portions 5 through the second bonding electrodes 62. Specifically, the conductive particles may be one or more of silver powder, gold powder, copper powder, and carbon powder.

As a conductive adhesive layer 7 may be arranged between the second bonding portions 5 and the second bonding electrodes 62, when the second bonding portions 5 may be misaligned with the second bonding electrodes 62, the second bonding portions 5 and the second bonding electrodes 62 may be electrically connected, avoiding a situation where the misalignment between the second bonding portions 5 and the second bonding electrodes 62 causes an increase in resistance and even bonding failure. In addition, the conductive adhesive layer 7 may also adhere the second bonding portions 5 to the second bonding electrodes 62, thereby enhancing the reliability of connection between the silicon-based driving substrate 6 and the glass substrate 1.

As shown in FIG. 1 and FIG. 2, in specific embodiments, the multiple second conductive vias 132 may be spaced apart and arranged around the multiple first conductive vias 131, and the multiple second bonding portions 5 may be arranged around the multiple first bonding portions 4, such that electrical contact points surrounding the multiple light-emitting units 2 may be formed on the entire cathode electrode 23. Consequently, the silicon-based driving substrate 6 may transmit cathode driving signals to the cathode electrode 23 through the circumferentially arranged the multiple second bonding portions 5 and the multiple second conductive vias 132, thereby improving the uniformity of the cathode driving signals and reducing voltage drop. In some embodiments, the first bonding portions 5 may be arranged in an array, and the at least one second bonding portion 4 may be arranged around the array, and the conductive adhesive layer 7 may be an annular conductive adhesive layer disposed around the array to cover and be in contact with the least one second bonding electrode 62 and the at least one second bonding portion 5. Every two adjacent ones of the first bonding portions 4 in a direction of the array have a same distance, and each of the at least one second bonding portion 5 may correspond to one of the first bonding portions 4.

As shown in FIG. 1 and FIG. 3, a conductive adhesive layer 7 may be an annular conductive adhesive layer 7 disposed around multiple first conductive vias 131. Circumferential edges of the glass substrate 1 and the silicon-based driving substrate 6 may be sealed by the annular conductive adhesive layer 7, so as to seal gaps between the silicon-based driving substrate 6 and the glass substrate 1, thereby isolating the external moisture and oxygen and avoid a situation where bonding failure occurs as the moisture and oxygen may be invaded and corroded into the first bonding portions 4 and the first bonding electrodes 61, as well as the second bonding portions 5 and the second bonding electrodes 62.

Specifically, along the stacking direction Z, two sides of the conductive adhesive layer 7 may be respectively attached to the glass substrate 1 and the silicon-based driving substrate 6, so as to seal the circumferential edges of the glass substrate 1 and the silicon-based driving substrate 6. At least part of a surface of the conductive adhesive layer 7 at a side towards the glass substrate 1 may cover at least part of each second bonding portion 5, and at least part of a surface of the conductive adhesive layer 7 at a side towards the silicon-based driving substrate 6 may cover at least part of each second bonding electrode 62, so as to ensure the electrical connection between a second bonding portion 5 and a corresponding second bonding electrode 62.

In specific embodiments, the conductive adhesive layer 7 may be an isotropic conductive adhesive layer with conductivity in all directions, so that when the second bonding portions 5 may be misaligned with the second bonding electrodes 62, the conductive adhesive layer 7 between the second bonding portions 5 and the second bonding electrodes 62 may provide more conductive channels, thereby achieving the purpose of reducing resistance. Those skilled in the art will understand that if the second bonding portions 5 may be directly and misalignedly bonded to the second bonding electrodes 62, a contact area between the second bonding portions 5 and the second bonding electrodes 62 would be small, and current may only be transmitted through locations at which the second bonding portions 5 and the second bonding electrodes 62 may be contacted, resulting in fewer conductive channels and increased resistance there between. As an annular auxiliary electrode 6 may be arranged between the second bonding portions 5 and the second bonding electrodes 62 and the annular auxiliary electrode 6 respectively may cover larger areas of both the second bonding portions 5 and the second bonding electrodes 62 compared with original contact areas, the conductive channels between the second bonding electrodes 62 and the annular auxiliary electrode 6 may be increased as well as the conductive channels between the annular auxiliary electrode 6 and the second bonding portions 5, thereby reducing the resistance.

As shown in FIG. 1, in specific embodiments, each second bonding portion 5 may be arranged over the corresponding second conductive via 132, and extend into the second conductive via 132 to contact the cathode electrode 23. A width a of the annular conductive adhesive layer 7 may be greater than a size b of the second bonding portion 5 in the width direction X of the annular conductive adhesive layer 7, and the annular conductive adhesive layer 7 may cover the multiple second bonding portions 5 and may be electrically connected to the second bonding portions 5 respectively, so as to increase a contact area between the annular conductive adhesive layer 7 and the second bonding portions 5, thereby providing more conductive channels between the annular conductive adhesive layer 7 and the second bonding portions 5, making it easier for the current to pass through, and further reducing a resistance between the annular conductive adhesive layer 7 and the second bonding portions 5.

Specifically, a projection of the second bonding portion 5 on the glass substrate 1 along the stacking direction Z may be located in a projection of the second conductive via 132 on the glass substrate 1 along the stacking direction Z. That is, in a plane perpendicular to the stacking direction Z, a second bonding portion 5 may be just arranged corresponding to the second conductive via 132, but do not extend on the second surface 12 of the glass substrate 1. Moreover, the projections of the multiple second bonding portions 5 on the glass substrate 1 along the stacking direction Z may be all located within the projection of the annular conductive adhesive layer 7 on the glass substrate 1 along the stacking direction Z, so that the annular conductive adhesive layer 7 completely may cover the multiple second bonding portions 5.

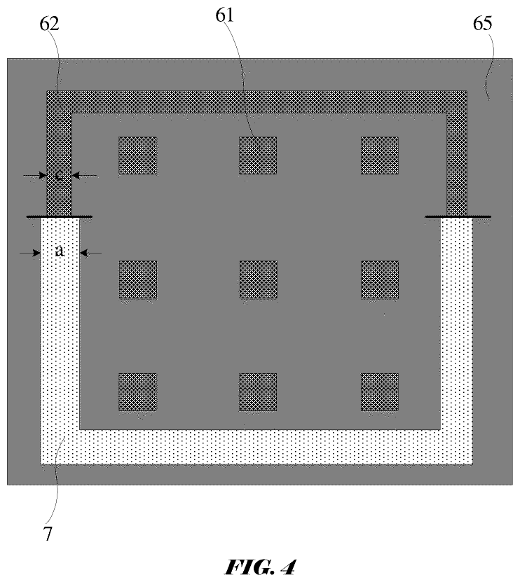

As shown in FIG. 4, which is a schematic structural view of the silicon-based driving substrate in the display panel shown in FIG. 1. In specific embodiments, the second bonding electrodes 62 may be an annular bonding electrode, and a width c of the annular bonding electrode may be less than a width a of the annular conductive adhesive layer 7, the annular conductive adhesive layer 7 may cover the annular bonding electrode, as so to increase a contact area between the second bonding electrodes 62 and the conductive adhesive layer 7, thereby further reducing the resistance between the second bonding electrodes 62 and the conductive adhesive layer 7. It may be understood that compared with multiple individual bonding electrodes, a larger contact area may be provided between the annular bonding electrode and the annular conductive adhesive layer 7, enabling more conductive channels therebetween and allowing current to pass more easily, thereby further reducing the resistance between the annular conductive adhesive layer 7 and the second bonding electrodes 62. In some embodiments, at least one second bonding electrode 62 may be an annular bonding electrode, and the annular bonding electrode may be covered by the annular conductive adhesive layer. Thus, a size of the annular bonding electrode may be less than a size of the annular conductive adhesive layer such that the annular bonding electrode is covered by the annular conductive adhesive layer.

Further, the second bonding portions 5 may also be an annular bonding portion, thereby further increasing a contact area between the second bonding portions 5 and the annular conductive adhesive layer 7, and reducing a resistance between the second bonding portions 5 and the conductive adhesive layer 7. In some embodiments, at least one second bonding portion 5 may be an annular bonding portion, and the annular bonding portion may be covered by the annular conductive adhesive layer. Thus, a size of the annular bonding portion may be less than a size of the annular conductive adhesive layer such that the annular bonding portion is covered by the annular conductive adhesive layer.

As shown in FIG. 1, in specific embodiments, the silicon-based driving substrate 6 may further include a silicon substrate 63 and a driving circuit layer 64 disposed on the silicon substrate 63. A projection of the driving circuit layer 64 on the silicon substrate 63 along the stacking direction Z may be located within the silicon substrate 63, and the driving circuit layer 64 may cover a part of a surface of the silicon substrate 63 close to the glass substrate 1, and exposes a part of a surface of the circumferential edge of the silicon substrate 63. The driving circuit layer 64 may be electrically connected to the multiple first bonding electrodes 61 and the multiple second bonding electrodes 62, respectively, thereby transmitting anode driving signals to the anode electrodes 21 through the first bonding electrodes 61 and cathode driving signals to the cathode electrode 23 through the second bonding electrodes 62. Specifically, the driving circuit layer 64 may include multiple “3T1C” structures (including three thin-film transistors and one capacitor) to achieve independent control and high-quality display of each light-emitting unit 2.

The silicon-based driving substrate 6 may further include a display control circuit (not shown) electrically connected to the driving circuit layer 64. The display control circuit controls the light-emitting units 2 to perform display through the driving circuit layer 64. The display control circuit may be an integrated circuit (IC) integrated on the silicon-based driving substrate 6.

As shown in FIG. 1, the silicon-based driving substrate 6 may further include a protection layer 65 covering a driving circuit layer 64. The protection layer 65 may be used to protect the driving circuit layer 64, so as to avoid external moisture and oxygen intrusion to corrode the circuit traces within the driving circuit layer 64. Specifically, the protection layer 65 may be disposed on a side of the driving circuit layer 64 away from the silicon substrate 63 and laps on a surface of the silicon substrate 63 not covered by the driving circuit layer 64, enabling the protection layer 65 to fully encapsulate the driving circuit layer 64 and isolate it from external moisture and oxygen. In some embodiments, the silicon-based driving substrate 6 may include a silicon substrate 63, a driving circuit layer 64 stacked on the silicon substrate 1, and a protection layer 65 stacked on covering the driving circuit layer 64. The corresponding second bonding electrodes 62 may extend from a surface at which of the driving circuit layer 64 and the protection layer 65 may be stacked towards a surface of the protection layer 65 in the stacking direction, and the corresponding first bonding electrode 61 may extend from the surface at which of the driving circuit layer 64 and the protection layer 65 may be stacked to the surface of the protection layer 65. The corresponding first bonding electrode 61 may have a surface flush with the surface of the protection layer 65. Each of the at least one second bonding portion 62 may extend from a first surface 11 of the glass substrate 1 beyond a second surface 12 of the glass substrate 1 towards the surface of the protection layer 65 in the stacking direction, and the each of the first bonding portions 4 may extend from the first surface 11 beyond the second surface 13 in the stacking direction to the surface of the protection layer 65 in the stacking direction. The first surface 11 is opposite to the second surface 12.

The protection layer 65 further may include multiple first vias 651, and both the first bonding electrodes 61 and the second bonding electrodes 62 may be embedded in the first vias 651 and electrically connected to the driving circuit layer 64. Specifically, the multiple first vias 651 may be arranged in one-to-one correspondence with the multiple first conductive vias 131 and second conductive vias 132, and each first via 651 may penetrate through a protection layer 65 along the stacking direction Z. The first bonding electrodes 61 may be disposed in a part of the first vias 651 corresponding to the first conductive vias 131 to electrically connect the driving circuit layer 64 to the first bonding portions 4. The second bonding electrodes 62 may be disposed in a part of the first vias 651 corresponding to the second conductive vias 132 to electrically connect the driving circuit layer 64 to the conductive adhesive layer. Specifically, the material of the protection layer 65 may be inorganic insulating materials such as silicon dioxide, silicon nitride, or silicon oxynitride.

As shown in FIG. 1 continually, further, an insulating layer 8 may cover the second surface 12 of the glass substrate 1, which may be used to protect the first bonding portions 4, the second bonding portions 5, and a conductive adhesive layer, avoid bonding failure caused by corrosion of the metal due to external moisture and oxygen. A surface of the insulating layer 8 away from the glass substrate 1 may abut against a surface of the protection layer 65 away from the silicon substrate 63. The insulating layer 8 may have second vias 81 at positions corresponding to the first conductive vias 131, and the second vias 81 may penetrate through the insulating layer 8 along the stacking direction Z. The first bonding portions 4 may be embedded in the second vias 81.

Specifically, a portion of a first bonding portion 4 close to an anode electrode 21 may be embedded in a first conductive via 131 and contact with the anode electrode 21, while a portion of a first bonding portion 4 close to a first bonding electrode 61 may be embedded in a second via 81 corresponding to the first conductive via 131 and contact with the first bonding electrode 61, thereby electrically connecting the first bonding electrode 61 to the anode electrode 21. A part of a second bonding portion 5 close to the cathode electrode 23 may be embedded in the second conductive via 132 and contact with the cathode electrode 23, while a part of the second bonding portion 5 close to the second bonding electrode 62 may be embedded in a second via 81 corresponding to the second conductive via 132 and contact with the conductive adhesive layer 7, thereby electrically connecting the conductive adhesive layer 7 and the cathode electrode 23.

As shown in FIG. 1, a part of the conductive adhesive layer 7 may be sandwiched between the second bonding portions 5 and the second bonding electrodes 62, such that the second bonding portions 5 and the second bonding electrodes 62 may be electrically connected. Thus, the cathode driving signal of the driving circuit layer 64 may be sequentially transmitted to the cathode electrodes 23 through the second bonding electrodes 62, the conductive adhesive layer 7, and the second bonding portions 5 to drive the light-emitting units 2 to emit light. Another part of the conductive adhesive layer 7 may be sandwiched between the protection layer 65 and the insulating layer 8 to ensure that the conductive adhesive layer 7 completely may cover the second bonding portions 5, and may also adhere the protection layer 65 to the insulating layer 8, further improving the connection reliability between the glass substrate 1 carrying the light-emitting units 2 and the silicon-based driving substrate 6.

Of course, in some other embodiments, the second bonding portions 5 may be misaligned with the second bonding electrode 62. In these embodiments, a part of the conductive adhesive layer 7 may be sandwiched between the second bonding portions 5 and the second bonding electrodes 62 to ensure the electrical connection between the second bonding portions 5 and the second bonding electrodes 62. In a part of the conductive adhesive layer 7 that may be not sandwiched between the second bonding portions 5 and the second bonding electrodes 62, at least part of the conductive adhesive layer 7 may be sandwiched between the protection layer 65 and the second bonding portions 5 to ensure that the contact area between the conductive adhesive layer 7 and the second bonding portions 5 may be large enough, thereby reducing the resistance between the conductive adhesive layer 7 and the second bonding portion 5. And/or, at least part of the conductive adhesive layer 7 may be sandwiched between the insulating layer 8 and the second bonding electrodes 62 to ensure that the contact area between the conductive adhesive layer 7 and the second bonding electrodes 62 may be large enough, thereby reducing the resistance between the conductive adhesive layer 7 and the second bonding electrodes 62. In some embodiments, the conductive adhesive layer 7 may have a first part sandwiched between the at least one second bonding portion 5 and the at least one second bonding electrode 62. In some embodiments, the conductive adhesive layer 7 further may have two second parts arranged at a respective side of the first part of the conductive adhesive layer 7. Each of two second parts may have a thickness greater than that of the first part of the conductive adhesive layer 7 in the stacking direction. In some embodiments, a thickness of each of the at least one second bonding portion 5, a corresponding second bonding electrode 62, and the first part of the conductive adhesive layer 7 in a stacking direction in which the glass substrate 1 and the silicon-based driving substrate 6 is stacked may be equal to a thickness of each of the first bonding portions 4 and a corresponding first bonding electrode 61 in the stacking direction. In some embodiments, a thickness of the each of the at least one second bonding portion 5 may be less than a thickness of the each of the first bonding portions 4, and a thickness of the corresponding second bonding electrode 62 may be less than a thickness of the corresponding first bonding electrode 61.

As shown in FIG. 1, in specific embodiments, a surface of the first bonding electrodes 61 away from the silicon substrate 63 may be flush with a surface of the protection layer 65 away from the silicon substrate 63, and a surface of the first bonding portions 4 away from the glass substrate 1 may be flush with a surface of the insulating layer 8 away from the glass substrate 1. Thus, after the first bonding electrodes 61 may be bonded to the first bonding portions 4, the surface of the protection layer 65 away from the silicon substrate 63 may be fitted to the surface of the insulating layer 8 away from the glass substrate 1, thereby avoiding a situation in which corrosion occurs as external moisture and oxygen may be infiltrated through any gap between the protection layer 65 and the insulating layer 8. Specifically, a height of a first bonding electrode 61 along the stacking direction Z may equal to a thickness of a protection layer 65 along the stacking direction Z, and a height of a first bonding portion 4 along the stacking direction Z may equal to a thickness of an insulating layer 8 along the stacking direction.

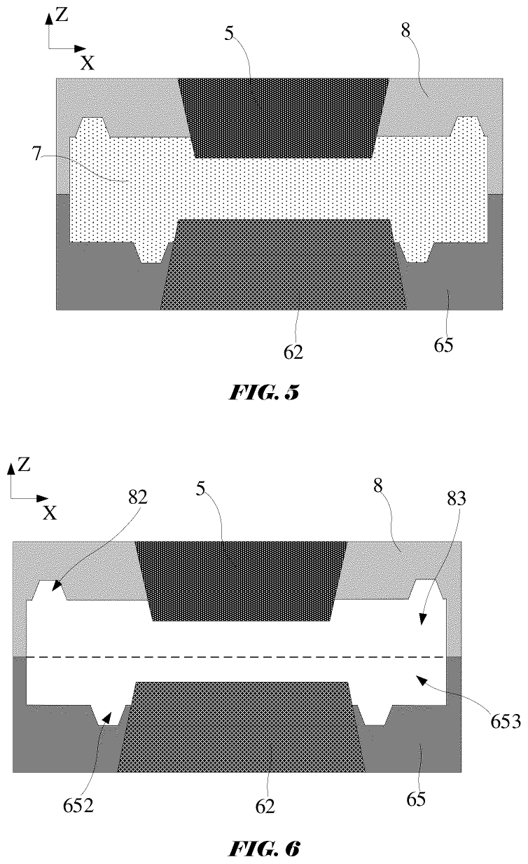

As shown in FIG. 5 and FIG. 6, FIG. 5 is a partially enlarged view of area A in the display panel shown in FIG. 1, FIG. 6 is a schematic structural view of the structure shown in FIG. 5 without the conductive adhesive layer. In combination with FIG. 1, a surface of the second bonding electrode 62 away from the silicon substrate 63 may be lower than a surface of the protection layer 65 away from the silicon substrate 63. That is, the second bonding electrode 62 may be completely located in the first via 651. A second bonding electrode 62 and a first via 651 form a first recessed structure 653, and thus, a part of the conductive adhesive layer 7 close to the silicon-based driving substrate 6 may be embedded in the first via 651 to form alignment when the conductive adhesive layer 7 may be arranged on the second bonding electrode 62. Thus, it may play an inducing role during alignment, improve the alignment accuracy, and limit the position of the conductive adhesive layer 7 to avoid problems such as displacement after alignment.

Specifically, a height of the second bonding electrode 62 along the stacking direction Z may be less than a depth of the first via 651 along the stacking direction Z. The second bonding electrode 62 may be higher than a bottom wall of the first recessed structure 653, and a side wall of the first recessed structure 653 may be spaced apart from a side wall of the second bonding electrode 62 such that the conductive adhesive layer 7 may be accommodated.

Similarly, the surface of the second bonding portion 5 away from the glass substrate 1 may also be lower than a surface of the insulating layer 8 away from the glass substrate 1. That is, the second bonding portion 5 may be completely located in the second via 81. The second bonding portion 5 and the second via 81 form a second recessed structure 83, and thus, a part of the conductive adhesive layer 7 close to the glass substrate 1 may be embedded in the second via 81 to form alignment when the glass substrate 1 may be bonded to the silicon-based driving substrate 6. It may play an inducing role during alignment, improve the alignment accuracy, and further limit the position of the conductive adhesive layer 7 to avoid problems such as displacement.

Specifically, a height of the second bonding portion 5 along the stacking direction Z may be less than a depth of the second via 81 along the stacking direction Z. The second bonding portion 5 may be higher than the bottom wall of the second recessed structure 83, and a side wall of the second recessed structure 83 may be spaced apart from a side wall of the second bonding portion 5 such that the conductive adhesive layer 7 may be accommodated.

As shown in FIG. 5 and FIG. 6, in specific embodiments, a surface of the protection layer 65 towards the insulating layer 8 may have a first groove 652, a part of the conductive adhesive layer 7 may be embedded in the first groove 652 to increase a contact area between the conductive adhesive layer 7 and the protection layer 65, thereby enhancing the adhesion between the conductive adhesive layer 7 and the protection layer 65. Specifically, as shown in FIG. 6, a first groove 652 may extend from a bottom wall of a first recessed structure 653 towards a silicon substrate 63 along the stacking direction Z, a part of a conductive adhesive layer 7 close to the protection layer 65 may be embedded in the first groove 652, and the other part may extend onto a bottom wall and aside wall of the first recessed structure 653.

Further, a surface of the insulating layer 8 towards the protection layer 65 may have a second groove 82, a part of a conductive adhesive layer 7 may be embedded in a second groove 82 to increase the contact area between the conductive adhesive layer 7 and the insulating layer 8, thereby enhancing the adhesion between the conductive adhesive layer 7 and the insulating layer 8. Specifically, a second groove 82 may extend from the bottom wall of a second recessed structure 83 towards the glass substrate 1 along the stacking direction Z, a part of the conductive adhesive layer 7 close to the insulating layer 8 may be embedded in the second groove 82, and the other part may extend onto a bottom wall and a side wall of the second recessed structure 83.

In this way, two sides of the conductive adhesive layer 7 along the stacking direction Z may be respectively embedded in a first groove 652 of a protection layer 65 and a second groove 82 of an insulating layer 8 to enhance the adhesion between the conductive adhesive layer 7 and the protection layer 65 as well as adhesion between the conductive adhesive layer 7 and the insulating layer 8. At the same time, a part of the conductive adhesive layer 7 embedded in a first groove 652 and a second groove 82 may further fix relative positions of a protection layer 65 and an insulating layer 8 in the width direction X of the conductive adhesive layer 7, thereby further enhancing the connection reliability between the glass substrate 1 and the silicon-based driving substrate 6. In addition, it may be understood that as both sides of the conductive adhesive layer 7 may be embedded in a first groove 652 and a second groove 82, a path for water and oxygen invasion may be prolonged, so as to further improve sealing performance of the conductive adhesive layer 7.

Further, a first groove 652 may also be misaligned with and a second groove 82 to further enhance the adhesion between a conductive adhesive layer 7 and the protection layer 65 as well as the adhesion between a conductive adhesive layer 7 and the insulating layer 8, thereby further enhancing connection reliability between the glass substrate 1 and the silicon-based driving substrate 6. Specifically, a projection of a first groove 652 on the conductive adhesive layer 7 along the stacking direction Z may be located outside a projection of a second groove 82 on the conductive adhesive layer 7 along the stacking direction Z.

Both the first groove 652 and the second groove 82 may be annular grooves. One of the first groove 652 and the second groove 82 may be located outside an annulus formed by the multiple second conductive vias 132, and the other one may be located inside the annulus formed by the multiple second conductive vias 132, so as to further enhance the adhesion between the conductive adhesive layer 7 and the protection layer 65 as well as the adhesion between the conductive adhesive layer 7 and the insulating layer 8, thereby further enhancing the connection reliability between the glass substrate 1 and the silicon-based driving substrate 6.

In some embodiments, both the number of the first groove 652 and the number of the second groove 82 may be multiple. A part of the multiple annular grooves may be located outside an annulus formed by the multiple second conductive vias 132, and a part of the multiple annular grooves may be located inside the annulus formed by the multiple second conductive vias 132, in order to further enhance the connection reliability between the glass substrate 1 and the silicon-based driving substrate 6. Meanwhile, a path for water and oxygen invasion may be further prolonged, so as to further improve the sealing performance of the conductive adhesive layer 7. In specific embodiments, the multiple first grooves 652 may be evenly distributed on both sides of the annulus formed by the multiple second conductive vias 132 along the width direction X, and the multiple second grooves 82 may also be evenly distributed on both sides of the annulus formed by the multiple second conductive vias 132 along the width direction X.

Of course, it may also be disposed that the multiple first grooves 652 may be located on one side of the annulus formed by the multiple second conductive vias 132 along the width direction X, and the multiple second grooves 82 may be located on the other side of the annulus formed by the multiple second conductive vias 132 along the width direction X.

In some other embodiments, a first groove 652 may only be arranged on a surface of the protection layer 65 towards an insulating layer 8, and a second groove 82 may be not arranged on a surface of the insulating layer 8 towards a protection layer 65. Alternatively, a second groove 82 may only be arranged on the surface of an insulating layer 8 towards a protection layer 65, and a first groove 652 may be not arranged on the surface of the protection layer 65 towards the insulating layer 8. It can be specifically set according to actual needs.

The present disclosure provides a display panel, the display panel includes a glass substrate 1, multiple light-emitting units 2, multiple first bonding portions 4, multiple second bonding portions 5, a silicon-based driving substrate 6, and a conductive adhesive layer 7. The glass substrate 1 may include a first surface 11 and a second surfaces 12. The glass substrate 1 may include multiple conductive vias 13 extending from the first surface 11 to the second surface 12 opposite to each other. The glass substrate 1 may include multiple conductive vias 13 extending from the first surface 11 to the second surface 12. The multiple conductive vias 13 may include multiple first conductive vias 131 and multiple second conductive vias 132. The multiple light-emitting units 2 may be disposed on the first surface 11 of the glass substrate 1. Each of the light-emitting units 2 may include an anode electrode, an organic light-emitting layer, and a cathode electrode, which sequentially stacked in a direction away from the glass substrate. The plurality of first bonding portion 4 may be arranged on the second surface 12 of the glass substrate 1. Each of the first bonding portions 4 may be at least partially disposed in a corresponding first conductive via 131. Each of the first bonding portions 4 may be electrically connected to the corresponding anode electrode 21 through the corresponding first conductive via 131. Each of the second bonding portions 5 may be at least partially disposed in a corresponding second conductive via 132. Each of the second bonding portions 5 may be electrically connected to the corresponding cathode electrode 23 through the corresponding second conductive via 132. A silicon-based driving substrate 6 may be disposed at a side of second surface 12 of the glass substrate 1, and the silicon-based driving substrate 6 may include multiple first bonding electrodes 61 and at least one second bonding electrode 62. The multiple first bonding electrodes 61 may be aligned and bonded to the multiple first bonding portions 4 in one-to-one correspondence. The conductive adhesive layer 7 may be arranged between the second bonding portions 5 and the second bonding electrodes 62 to conduct and adhere the second bonding portions 5 and the second bonding electrodes 62 together. As the light-emitting units 2, the first bonding portions 4 and the second bonding portions 5 may be arranged on the two opposing surfaces of the glass substrate 1 respectively, the first bonding portions 4 are contacted with and electrically connected with the anode electrodes 21 of the corresponding light-emitting units 2 through the first conductive vias 131, and the second bonding portions 5 are contacted with and electrically connected with the cathode electrodes 132 of the light-emitting units 2 through the second conductive vias 132. Thus, after the first bonding portions 4 and the second bonding portions 5 are bonded to the first bonding electrodes 61 and the second bonding electrodes 62 of the silicon-based driving substrate 6 respectively, the electrical coupling between the light-emitting units 2 and the silicon-based driving substrate 6 is realized, enabling the silicon-based driving substrate 6 to drive the light-emitting units 2 to emit light. In this way, the light-emitting units 2 first may be fabricated on the glass substrate 1 and then bonded to the silicon-based driving substrate 6, rather than the light-emitting units 2 being directly fabricated on the silicon-based driving substrate 1, thereby avoiding the problem of damaging to pixel driving circuits and then resulting in a reduction in the product yield which is caused by directly fabricating the light-emitting units 2 on the silicon-based driving substrate 7. Furthermore, as a conductive adhesive layer 7 may be arranged between the second bonding portions 5 and the second bonding electrodes 62, when the second bonding portions 5 may be misaligned with the second bonding electrodes 62, the second bonding portions 5 and the second bonding electrodes 62 may be electrically connected, avoiding a situation where the misalignment between the second bonding portions and the second bonding electrodes causes an increase in resistance and even bonding failure. In addition, the conductive adhesive layer 7 may also adhere the second bonding portions 5 to the second bonding electrode 62, thereby enhancing the reliability of connection between the silicon-based driving substrate 6 and the glass substrate 1.

The above description are only embodiments of the present disclosure, and do not limit the scope of the present disclosure. Any equivalent structure or equivalent process transformation made by using the contents of the description and drawings of the present disclosure, or directly or indirectly used in other related technical fields, are similarly comprised in the scope of patent protection of the present disclosure.

1. A display panel, comprising:
a glass substrate, comprising a first surface and a second surface opposite to each other and having a plurality of conductive vias extending from the first surface to the second surface; the plurality of conductive vias comprising a plurality of first conductive vias and a plurality of second conductive vias;
a plurality of light-emitting units, disposed on the first surface of the glass substrate; each of the light-emitting units comprising an anode electrode, an organic light-emitting layer, and a cathode electrode sequentially stacked in a direction away from the glass substrate;
a plurality of first bonding portions, each of the first bonding portions being electrically connected to a corresponding anode electrode through a corresponding first conductive via of the first conductive vias;
a plurality of second bonding portions, each of the second bonding portions being electrically connected to a corresponding cathode electrode through a corresponding second conductive via of the second conductive vias;
a silicon-based driving substrate, disposed on the second surface of the glass substrate, comprising a plurality of first bonding electrodes and a plurality of second bonding electrodes; the plurality of first bonding electrodes being aligned and bonded to the plurality of first bonding portions in one-to-one correspondence;
a conductive adhesive layer, configured to conduct and adhere the second bonding portions to the second bonding electrodes together.

2. The display panel according to claim 1, wherein the plurality of second conductive vias are spaced apart and disposed around the plurality of first conductive vias; the plurality of second bonding portions are disposed around the plurality of first bonding portions;
the conductive adhesive layer is an annular conductive adhesive layer disposed around the plurality of first conductive vias, and circumferential edges of the glass substrate and the silicon-based driving substrate are sealed by the annular conductive adhesive layer.

3. The display panel according to claim 2, wherein each of the second bonding portions is disposed in a corresponding second conductive via of the second conductive vias, a width of the annular conductive adhesive layer is greater than a size of the corresponding second bonding portion in a width direction of the annular conductive adhesive layer, and the annular conductive adhesive layer covers the plurality of second bonding portions.

4. The display panel according to claim 3, wherein the silicon-based driving substrate comprises:
a silicon substrate,
a driving circuit layer disposed on the silicon substrate, and
a protection layer covering the driving circuit layer and defining a plurality of first vias; wherein each of both the first bonding electrode and the second bonding electrode is embedded in a corresponding one of the first vias and electrically connected to the driving circuit layer;
an insulating layer covers the second surface of the glass substrate, and the insulating layer comprises a second via at a position corresponding to each of the conductive vias, wherein each of the first bonding portions and the second bonding portions is embedded in a corresponding second via;
wherein a part of the conductive adhesive layer is sandwiched between the second bonding portion and the second bonding electrode, and another part of the conductive adhesive layer is sandwiched between the protection layer and the insulating layer.

5. The display panel according to claim 4, wherein a surface of the protection layer towards the insulating layer has a first groove, and the conductive adhesive layer is partially embedded in the first groove; and/or
a surface of the insulating layer towards the protection layer has a second groove, and the conductive adhesive layer is partially embedded in the second groove.

6. The display panel according to claim 5, wherein the surface of the protection layer towards the insulating layer has a first groove, and the surface of the insulating layer towards the protection layer has a second groove; the first groove is misaligned with the second groove in different lines of a direction in which the glass substrate and the silicon-based driving substrate are stacked.

7. The display panel according to claim 6, wherein both the first groove and the second groove are annular grooves; a part of the annular grooves are located outside an annulus formed by the plurality of second conductive vias, and a part of the annular grooves are located inside the annulus formed by the plurality of second conductive vias.

8. The display panel according to claim 4, wherein a surface of each of the first bonding electrodes away from the silicon substrate is flush with a surface of the protection layer away from the silicon substrate of the silicon-based driving substrate; a surface of each of the second bonding electrodes away from the silicon substrate is lower than the surface of the protection layer away from the silicon substrate in a direction from the silicon substrate to the protection layer, and the conductive adhesive layer is partially embedded in the first vias; and/or
a surface of each of the first bonding portions away from the glass substrate is flush with a surface of the insulating layer away from the glass substrate; a surface of each of the second bonding portions away from the glass substrate is lower than a surface of the insulating layer away from the glass substrate in a direction from the insulating layer to the glass substrate, and the conductive adhesive layer is partially embedded in the second vias.

9. The display panel according to claim 2, wherein the second bonding electrodes are an annular bonding electrode, a width of the annular bonding electrode is less than a width of the annular conductive adhesive layer, and the annular conductive adhesive layer covers the annular bonding electrode.

10. The display panel according to claim 1, wherein the conductive adhesive layer is an isotropic conductive adhesive layer.

11. A display panel, comprising:
a glass substrate, comprising a plurality of first bonding portions and at least one second bonding portion, wherein each of the first bonding portions is electrically connected to a corresponding anode electrode, and each of the at least one second bonding portion is electrically connected to a corresponding cathode electrode;
a silicon-based driving substrate, aligned and bonded to the glass substrate, wherein the silicon-based driving substrate comprises a plurality of first bonding electrodes and at least one second bonding electrode; the plurality of first bonding electrodes are aligned and bonded to the plurality of first bonding portions in one-to-one correspondence; and
a conductive adhesive layer, configured to conduct and adhere the at least one second bonding portion to the at least one second bonding electrode together.

12. The display panel according to claim 11, wherein the first bonding portions are arranged in an array, and the at least one second bonding portion is arranged around the array;
the conductive adhesive layer is an annular conductive adhesive layer disposed around the array to cover and be in contact with the least one second bonding electrode and the at least one second bonding portion.

13. The display panel according to claim 12, wherein every two adjacent ones of the first bonding portions in a direction of the array have a same distance, and each of the at least one second bonding portion corresponds to one first bonding portion of the first bonding portions.

14. The display panel according to claim 12, wherein the at least one second bonding electrode is an annular bonding electrode, wherein the annular bonding electrode is covered by the annular conductive adhesive layer; and/or
the at least one second bonding portion is an annular bonding portion, wherein the annular bonding portion is covered by the annular conductive adhesive layer.

15. The display panel according to claim 14, wherein a size of the annular bonding electrode is less than a size of the annular conductive adhesive layer such that the annular bonding electrode is covered by the annular conductive adhesive layer; and/or
a size of the annular bonding portion is less than a size of the annular conductive adhesive layer such that the annular bonding portion is covered by the annular conductive adhesive layer.

16. The display panel according to claim 11, wherein the conductive adhesive layer has a first part sandwiched between the at least one second bonding portion and the at least one second bonding electrode;
a thickness of each of the at least one second bonding portion, a corresponding second bonding electrode, and the first part of the conductive adhesive layer in a stacking direction in which the glass substrate and the silicon-based driving substrate are stacked is equal to a thickness of each of the first bonding portions and a corresponding first bonding electrode in the stacking direction.

17. The display panel according to claim 16, wherein a thickness of the each of the at least one second bonding portion is less than a thickness of the each of the first bonding portions;
a thickness of the corresponding second bonding electrode is less than a thickness of the corresponding first bonding electrode.

18. The display panel according to claim 17, wherein the silicon-based driving substrate comprises:
a silicon substrate,
a driving circuit layer stacked on the silicon substrate, and
a protection layer stacked on covering the driving circuit layer;
the corresponding second bonding electrode extends from a surface at which of the driving circuit layer and the protection layer are stacked towards a surface of the protection layer in the stacking direction, and the corresponding first bonding electrode extends from the surface at which of the driving circuit layer and the protection layer are stacked to the surface of the protection layer, wherein the corresponding first bonding electrode has a surface flush with the surface of the protection layer;
wherein the each of the at least one second bonding portion extends from a first surface of the glass substrate beyond a second surface of the glass substrate towards the surface of the protection layer in the stacking direction, and the each of the first bonding portions extends from the first surface beyond the second surface in the stacking direction to the surface of the protection layer in the stacking direction, wherein the first surface is opposite to the second surface.

19. The display panel according to claim 16, wherein the conductive adhesive layer further has two second parts arranged at a respective side of the first part of the conductive adhesive layer, wherein each of two second parts has a thickness greater than that of the first part of the conductive adhesive layer in the stacking direction.

20. A display panel, comprising:
a glass substrate, comprising a plurality of first bonding portions and at least one second bonding portion;
a plurality of light-emitting units, disposed on the glass substrate, wherein each of the light-emitting units comprises an anode electrode, an organic light-emitting layer, and a cathode electrode sequentially stacked on the glass substrate, a corresponding anode electrode is electrically connected to a corresponding one of the first bonding portions, and a corresponding cathode electrode is electrically connected to a corresponding one of the at least one second bonding portion;
a silicon-based driving substrate, aligned and bonded to the glass substrate, wherein the silicon-based driving substrate comprises a plurality of first bonding electrodes and at least one second bonding electrode; the plurality of first bonding electrodes are aligned and bonded to the plurality of first bonding portions in one-to-one correspondence; and
a conductive adhesive layer, configured to conduct and adhere the at least one second bonding portion to the at least one second bonding electrode together.
